(19) United States
(12) Patent Application Publication
(10) Pub. No.: US 2025/0149304 A1
(43) Pub. Date: May 8, 2025

(54) SYSTEM FOR CONTROLLING A SLOPE AND LOCATION OF AN UPPER ELECTRODE

(71) Applicant: VM Inc., Icheon-si (KR)

(72) Inventors: Sang Woo LEE, Suwon-si (KR); Woo Hyung CHOI, Seongnam-si (KR); Tae Jin KWON, Anseong-si (KR)

(21) Appl. No.: 18/789,601

(22) Filed: Jul. 30, 2024

(30) Foreign Application Priority Data
Nov. 6, 2023 (KR) 10-2023-0151688

(51) Int. Cl. H01J 37/32

(52) U.S. Cl. CPC H01J 37/32568; H01J 37/3244; H01J 2237/3341

(57) ABSTRACT

A system for controlling a slope and a location of an upper electrode comprises an upper electrode module 11 disposed to face a lower electrode 13 of a process chamber C; a lid 12 coupled to an upper part of the process chamber C; at least three motors 14a, 14b disposed at an upper surface of the lid 12; and a connecting means for connecting the at least three motors 14a, 14b to the upper electrode module 11 respectively.

### BACKGROUND OF THE INVENTION

### Field of the Invention

The present invention relates to a system for controlling a slope and location of an upper electrode, in particular the system capable of controlling a process volume by regulating the location or the slope of the upper electrode with respect to a lower electrode.

### Description of the Related Art

A semiconductor pattern has been gradually changing in minute form for forming a structure of a high integration and a high efficiency of the semiconductor element, and accordingly a capacity for manufacturing the semiconductor element has been being developed by applying various substances. With such development, the pattern has been gradually more minute and the structure has been more complicate and deeper to increase the total process numbers and the difficulty of each process rapidly. It is indispensable to maintain and enhance a yield rate of the wafer for performing a process of a high difficult level under considering a producing capacity, and accordingly, a process factor such as a uniformity of the total process, a product amount per hour or a formation of a process profile has been emerging rapidly as a competitiveness of a process equipment. Various semiconductor equipment manufacturers have been making an effort to develop various fixing factors such as an improvement of a temperature uniformity, a regulation of a plasma density or a regulation of a sheath area for enhancing the corresponding major performance. In particular, in recent years, a complex process including such as a use of different process gases in plurality of etching steps contained in one process and a use of RF output of various wavelength bands RF is required and a point of limit has been appearing in a known control knob. Therefore, a utility of an additional control knob is being required. For example, a space gap between the upper electrode and the lower electrode or a space structure formed between the upper electrode and the lower electrode needs to be regulated for a uniformity improvement of an etching process and a control of a process gap. But, the prior art or the known skill does not describe a technology to control the space gap or the space structure.

The present invention is intended to solve the problem of the prior art and has the following purpose.

### PURPOSE OF THE INVENTION

The object of the present invention is to provide with a system capable of controlling a slope and location of an upper electrode by a motor, wherein the real time location and the real time slope of the upper electrode are controlled using the electrical motor, and hence the system can be utilized as a control knob of an etching profile through a uniformity improvement of an etching process and a process gap control.

### SUMMARY OF THE INVENTION

In one embodiment of the present invention, a system for controlling a slope and a location of an upper electrode comprises an upper electrode module disposed to face a lower electrode of a process chamber; a lid coupled to an upper part of the process chamber; at least three motors disposed at an upper surface of the lid; and connecting means for connecting the at least three motors to the upper electrode module 11 respectively.

In other embodiment of the present invention, the slope or the location of the upper electrode module is regulated according to an operation of the connecting means driven by the at least three motors.

In another embodiment of the present invention, the connecting means are arranged with respective bellows units.

In still another embodiment of the present invention, the at least three motors are disposed separately at different edge portions of the lid.

In still another embodiment of the present invention, the at least three motors are disposed separately at different center portions of the lid.

In still another embodiment of the present invention, the at least three motors are connected to the upper electrode module by the connecting means through one guiding hole by the connecting means.

In still another embodiment of the present invention, the system further comprises a shower head disposed at a lower part of the upper electrode module, and the shower head comprises an inclined guiding portion inclined in an outward direction.

In still another embodiment of the present invention, the system further comprises a purge gap formed along a circumferential side of the upper electrode module.

In still another embodiment of the present invention, the system comprises a grounding ring coupled to a surrounding surface of the upper electrode module, and the grounding ring comprises a ring base in a circular shape and a plurality of flowing holes formed along the ring base.

In still another embodiment of the present invention, the grounding ring has an elastic property.

### BRIEF DESCRIPTION OF THE DRAWINGS

FIG. 1 shows an embodiment of a system for controlling a slope and location of an upper electrode according to the present invention.

FIG. 2 shows an embodiment of a motor arrangement structure for the system according to the present invention.

FIG. 3 shows an embodiment of a center motor controlling structure in the system according to the present invention.

FIG. 4 shows an embodiment of a side wall structure in the system according to the present invention.

FIG. 5 shows an embodiment of a gas purging structure in the system according to the present invention.

FIG. 6 shows an embodiment of an electrode grounding structure in the system according to the present invention.

### DETAILED DESCRIPTION OF EXEMPLARY EMBODIMENTS

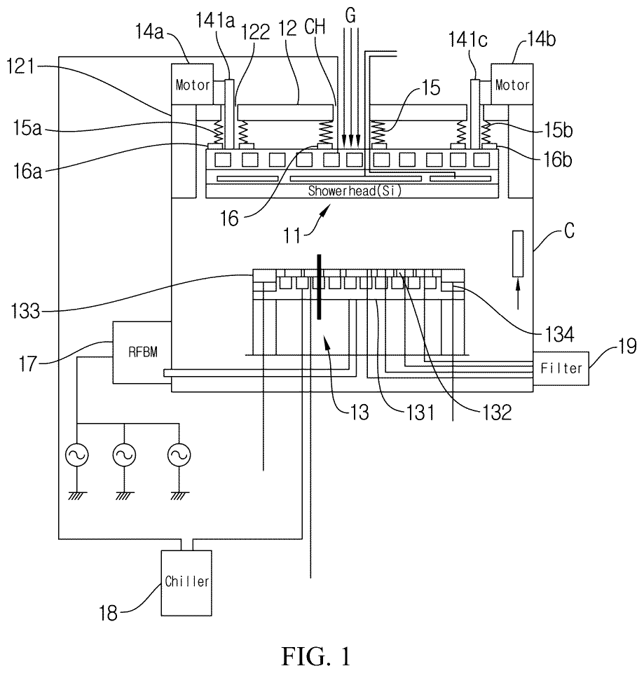

FIG. 1 shows an embodiment of a system for controlling a slope and location of an upper electrode according to the present invention.

Referring to FIG. 1, a system for controlling a slope and a location of an upper electrode comprises an upper electrode module 11 disposed to face a lower electrode 13 of a process chamber C; a lid 12 coupled to an upper part of the process chamber C; at least three motors 14a, 14b disposed at an upper surface of the lid 12; and a connecting means for connecting the at least three motors 14a, 14b to the upper electrode module 11 respectively.

The process chamber C may become a vacuum chamber, and the process chamber C may become a volume for performing a semiconductor process such as an etching process of wafer with a plasma. The lower electrode module 13 where an electrostatic chuck 131 is located on an upper surface may be placed within the process chamber C. And the upper electrode module 11 facing the lower electrode module 13 may be placed at an upper part of the process chamber C. The lower electrode module 13 may comprise a lower electrode; the electrostatic chuck 131 placed on the upper surface of the lower electrode; a heater 132 disposed within the electrostatic chuck 131 and regulating the temperature of the wafer; an edge ring 133; and an edge ring heater 134. An RF power with different frequencies may be applied to the lower electrode by a controller 17, and a coolant for maintaining the temperature of the electrostatic chuck 131 may be supplied by a chiller or cooling device 18. And also, the power may be supplied through a filter unit 19 for operating the heater 132. The lid 12 may be coupled to the upper part of the process chamber C to seal the process chamber C, and the lid 12 may become a circular plate shape to be coupled to a border block 121 surrounding the upper part of the process chamber C.

The upper electrode module 11 may be disposed under the lid 12, and the upper electrode module 11 may be connected structurally to the at least three motors 14a, 14b placed at the upper surface of the lid 12. The third motor 14c and its relevant elements are left out sometimes herein for convenience' sake. Specifically, a vertical position of the upper electrode module 11 or a slope of the upper electrode module 11 may be adjusted by an operation of the motors 14a, 14b. The lid 12 may have a circular plate shape, and the at least three motors 14a, 14b may be placed at different positions of the upper surface of the lid 12. For example, three motors 14a, 14b may be arranged separately each other with a circumferential angle of 120 degrees along the edge of the lid 12. And also, three motors 14a, 14b may be arranged at the center part of the lid 12 with a circumferential angle of 120 degrees. Guiding holes 122 corresponding to each motor 14a, 14b may be formed at the lid 12, and operating shafts 141a, 141b may be introduced through the guiding holes 122. Each motor 14a, 14b may be connected to one end of each operating shaft 141a, 141b, and the other end of each operating shaft 141a, 141b may be coupled to the upper surface of the upper electrode module 11. For example, a pinion gear may be coupled to each motor shaft, and each operating shaft 141a, 141b may have a rack gear structure. And each operating shaft 141a, 141b may move up and down by an operation of each motor 14a, 14b. The motors 14a, 14b may be connected to the operating shafts 141a, 141b in various ways for moving the upper electrode module 11 up and down, but not limited to.

The guiding holes 122 may be sealed to the inside of the chamber C, and hence, guiding paths 15a, 15b enclosing the guiding holes 122 may be formed. The guiding paths 15a, 15b may have a structure of connecting the lower surface of the lid 12 to the upper surface of the upper electrode module 11. The guiding paths 15a, 15b may be made as a structure capable of stretching in a vertical direction, for example, the guiding paths 15a, 15b may be made as a bellows structure or a corrugated pipe structure. Hence, as the operating shafts 141a, 141b move up and down, a top and bottom length of the guiding paths 15a, 15b may be regulated. A portion where the end parts of the guiding paths 15a, 15b contact the upper surface of the upper electrode module 11 may be sealed to block a gas from flowing between the guiding paths 15a, 15b and the inner part of the process chamber C.

A center hole CH may be formed at the center of the lid 12, and a center guiding path 15 may be formed at the center hole CH. The center guiding path 15 may have a structure similar to the guiding paths 15a, 15b, and the upper end of the guiding path 15 may contact the lower surface of the lid 12, and the lower end of the center guiding path 15 may be coupled to the upper surface of the upper electrode module 11. A center sealing unit 16 may be formed at a portion where the lower end of the center guiding path 15 contact the upper surface of the upper electrode module 11. And also, the center guiding path 15 may be made as a structure with a stretching property in a vertical direction, for example, the center guiding path 15 may be made as a bellows structure or a corrugated pipe structure. A coolant line may be guided to the upper electrode module 11 through the center guiding path 15 formed in this way. And also, a power line for supplying a power to a heat unit disposed within the upper electrode module 11 may be guided through the center guiding path 15, and a gas G may be input through the center guiding path 15. It is possible for the upper electrode module to move up and down by such structure of the guiding paths 15a, 15b and the center guiding path 15.

The vertical position of the upper electrode module 11 may be determined by the at least three operating shafts 141a, 141b operated by the at least three motors 14a, 14b, and the distance between the upper electrode module 11 and the lower electrode module 13 may be regulated. And also, the slope of the upper electrode module 11 may be regulated by a vertical movement of at least one of the operating shafts 141a, 141b operated by at least one of the motors 14a, 14b. The at least three motors 14a, 14b may be arranged on the upper surface of the lid 12 in various ways, but not limited to.

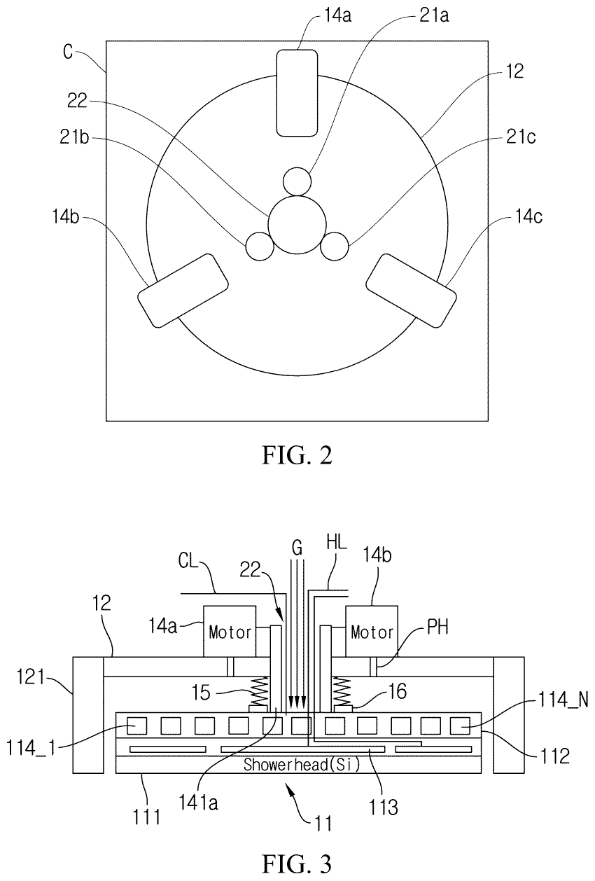

FIG. 2 shows an embodiment of a motor arrangement structure for the system according to the present invention.

Referring to FIG. 2, three motors 14a, 14b, 14c may be arranged in an edge part of the lid 12 with each motor 14a, 14b, 14c having a circumferential angle of 120 degrees. In such arranging structure, each guiding hole is formed at the lid 12 for each motor 14a, 14b, 14c, and three guiding paths may be formed based on three guiding holes. On the contrary, when three motors 14a, 14b, 14c are disposed at three separating locations, one center guiding hole 22 may be formed and three operating shafts operated by three motors 14a, 14b, 14c may be disposed at one center guiding hole. Therefore, according to one embodiment of the present invention, three motors 14a, 14b, 14c may be disposed at three center separating locations 21a, 21b, 21c. Three center separating locations 21a, 21b, 21c may arranged along the edge of the center guiding hole 22 with a circumferential angle of 120 degrees. The present invention will be discussed in detail based on this arranging structure in the following. However, the number of the motors 14a, 14b, 14c may be three or more, but not limited to.

FIG. 3 shows an embodiment of a center motor controlling structure in the system according to the present invention.

Referring to FIG. 3, three motors 14a, 14b may be arranged at the center separating location, the center guiding hole 22 may be formed at a center of three motors 14a, 14b, and one guiding path 15 may be formed based on the center guiding hole 22. The guiding path 15 may have a structure capable of stretching in a vertical or have an elastic structure, for example, the guiding path 15 may be made as a bellows structure or a corrugated pipe. And also, the sealing unit 16 may be formed at a portion where the lower end of the guiding path 15 is coupled to the upper surface of the upper surface of the upper electrode module 11. The operating shafts 141a, 141b connected to each motor 14a, 14b may extend along the guiding path 15 having such structure. The lower end of each operating shaft 141a, 141b may contact the upper surface of the upper electrode module 11. The coolant line CL may be introduced along the inner part of the guiding path 15, and the line for supplying a power to the heater 113 disposed at the upper electrode module 11 may be introduced to the upper electrode module 11 along the guiding path 15. And a gas G for performing a process may be input into the chamber through the guiding path 15. And also, a gas for a purge may be input into the chamber through the purging hole PH formed at lid 12 via the upper surface of the upper electrode module 11.

The upper electrode module 11 may comprise the shower head 111; the heating block 112 disposed at the upper part of the shower head 111; a head heater 113 disposed at the upper surface of the shower head 111; and a plurality of cooling paths 141_1 to 141_N. The lower end parts of three operating shafts 141a, 141b may contact three different locations based on the center of the upper surface of the upper electrode module 11. For example, three lower end parts may contact three positions corresponding to three vertices of an equilateral triangle to move the upper electrode module 11 up and down. And also, three operating shafts 141a, 141b may operate selectively for regulating the slope of the upper electrode module 11. Three motors 14a, 14b may operate independently each other, hence each operating shaft 141a, 141b may apply the same or different forces independently to three different locations of the upper surface of the upper electrode module 11. The vertical position or the slope of the upper electrode module 11 may be determined according to the forces applied by three operating shafts 141a, 141b. Accordingly, a means for measuring the force applied by the operating shafts 141a, 141b or a traveled distance of each operating shaft 141a, 141b may be prepared. For example, the traveled distance of each operating shaft 141a, 141b may be detected by an optical means with a linear scaler. A distance of the upper electrode module 11 relative to the lower electrode module 11 may be measured by the traveled distance of each operating shaft 141a, 141b detected by the optical means, and at the same time a parallel condition of the upper electrode module 11 may be checked. The location or the slope of the upper electrode module 11 may be detected in various ways, but not limited to.

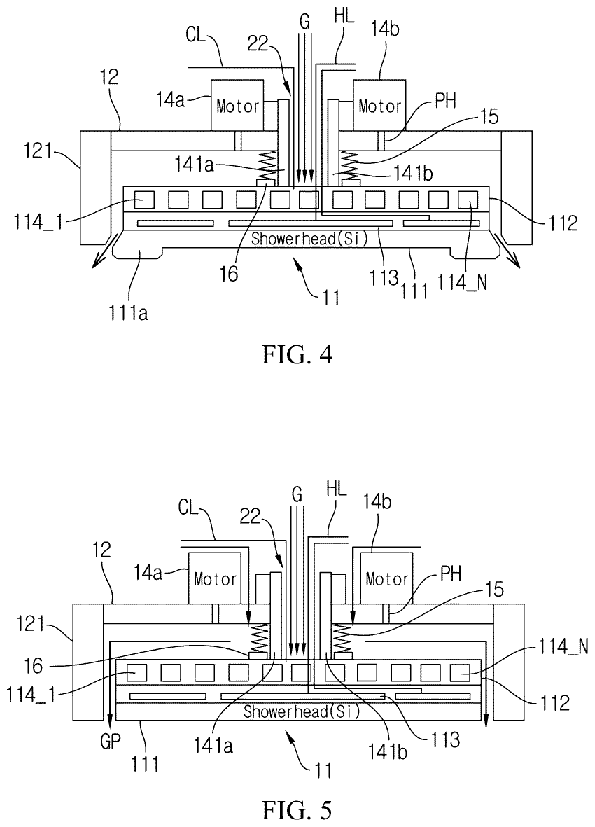

FIG. 4 shows an embodiment of a side wall structure in the system according to the present invention.

Referring to FIG. 4, the system comprises the shower head 111 disposed at the lower part of the upper electrode module 11, and the shower head 111 comprises an inclined guiding portion 111a inclined in an outward direction. The upper electrode module 11 and the shower head 111 may have a circular plate shape.

The gas existing above the surface of the upper electrode module 11 may be purged along a gap formed at the surrounding surface of the upper electrode module 11. The edge of the shower head 111 may be inclined from top to bottom in order that the gas G cannot affect the process volume as the gas discharges quickly, accordingly, the inclined guiding portion 111a may be formed at the edge part of the shower head 111. And an inclined guiding gap GP may be formed along a perimeter of the border block 121 and the shower head 111. And the gas can be discharged quickly and does not affect the process volume by such inclined guiding gap GP. The inclined guiding gap GP may have various extending length, but not limited to.

FIG. 5 shows an embodiment of a gas purging structure in the system according to the present invention.

Referring to FIG. 5, the system comprises a purge gap formed along the circumferential side of the upper electrode module 11. The process gas input through the center guiding hole 22 may flow along the guiding path 15 to enter the chamber. And also, the purge gas may be introduced along a purge hole PH formed at the lid 12 to flow between the upper electrode module 11 and the lid 12, and then the purge gas may flow along the purge gap GP formed between the upper electrode module 11 and the circumferential inner side wall of the chamber. For example, an inert gas with a low reactivity such as nitrogen or argon may be introduced through the center guiding hole 22 to flow the guiding path 15. Thereby, the gas existing within the vacuum chamber or the plasma may be prevented from flowing upward and an intermediate product may be prevented from being deposited at the upper volume to limit a particle generation. To this end, the edge of the shower head may be formed in an inclined shape, as described above. And also, a ground ring may be disposed along the circumferential side of the shower head as described below.

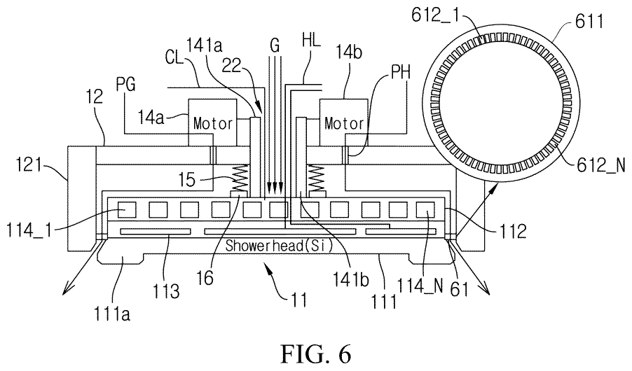

FIG. 6 shows an embodiment of an electrode grounding structure in the system according to the present invention.

Referring to FIG. 6, the system comprises a ground ring 61 coupled to the perimeter side of the upper electrode module 11, and the ground ring 61 may comprise a circular ring base 611 and a plurality of flowing holes 612_1 to 612_N formed along the ring base 611. The inclined guiding portion 111a may be formed at the edge part of the shower head 111, and the ground ring 61 may be disposed at a perimeter of the upper surface of the shower head 111. The ground ring 61 may have a circular ring shape, and the ground ring 61 may comprise the circular ring base 611 and the plurality of flowing holes 612_1 to 612_N formed along the ring base 611. The ring base may become a ring shape with a rectangular cross section, and the plurality of flowing holes 612_1 to 612_N which allow the gas to flow may be formed along an inner portion of the ring base 611. The ground ring 61 may be located at the purge gap formed between the edge of the shower head and the inner surface of the circumferential wall of the chamber. The gas G introduced along the center guiding hole 22 may flow along the guiding path 15 to enter the chamber through the shower head 111. And also, the purge gas G may be introduced to the upper part of the upper electrode module 11 through the purge hole PH. And then, the purge gas PG may flow along the purge gap formed at the perimeter side of the upper electrode module 11 to flow through the plurality of the flowing holes 612_1 to 612_N of the ground ring 61 and then flow along the inclined guiding portion 111a. The ground ring may be made from a stretchable or an elastic material, thereby a size of each flowing hole 612_1 to 612_N may be regulated according to the coupled position of the upper electrode module 11. The ground ring 61 may be made as various structures, but not limited to.

What is claimed is:

1. A system for controlling a slope and a location of an upper electrode, comprising:
an upper electrode module disposed to face a lower electrode of a process chamber C;
a lid coupled to an upper part of the process chamber;
at least three motors disposed at an upper surface of the lid; and
connecting means for connecting the at least three motors to the upper electrode module respectively.

2. The system according to claim 1, wherein the slope or the location of the upper electrode module is regulated according to an operation of the connecting means driven by the at least three motors.

3. The system according to claim 1, wherein the connecting means are arranged within respective bellows units.

4. The system according to claim 1, wherein the at least three motors are disposed separately at different edge portions of the lid.

5. The system according to claim 1, wherein the at least three motors are disposed separately at different center portions of the lid.

6. The system according to claim 5, wherein the at least three motors are connected to the upper electrode module by the connecting means through one guiding hole by the connecting means.

7. The system according to claim 1, wherein the system further comprises a shower head disposed at a lower part of the upper electrode module, and the shower head comprises an inclined guiding portion inclined in an outward direction.

8. The system according to claim 1, wherein the system further comprises a purge gap formed along a circumference of the upper electrode module.

9. The system according to claim 1, wherein the system comprises a grounding ring coupled to a surrounding surface of the upper electrode module, and the grounding ring comprises a ring base in a circular shape and a plurality of flowing holes formed along the ring base.

10. The system according to claim 9, wherein the grounding ring has an elastic property.
